(19) United States
(12) Patent Application Publication
(10) Pub. No.: US 2021/0156902 A1
(43) Pub. Date: May 27, 2021

(54) SEMICONDUCTOR CHIP AND CIRCUIT AND METHOD FOR ELECTRICALLY TESTING SEMICONDUCTOR CHIP

(71) Applicant: Changxin Memory Technologies, Inc., Hefei (CN)

(72) Inventor: Weibao KE, Hefei (CN)

(21) Appl. No.: 17/168,175

(22) Filed: Feb. 5, 2021

Related U.S. Application Data
(63) Continuation of application No. PCT/CN2019/103420, filed on Aug. 29, 2019.

(30) Foreign Application Priority Data
Sep. 6, 2018 (CN) 201811037719.7
Sep. 6, 2018 (CN) 201821459275.1

(51) Int. Cl. G01R 31/26; G01R 1/073

(52) U.S. Cl. CPC G01R 31/2628; G01R 1/07342; G01R 31/2644

(57) ABSTRACT

A semiconductor chip and a circuit and a method for electrically testing a semiconductor chip are disclosed, which pertain to the field of semiconductor technology. The semiconductor chip includes: a first electrical connection point, configured to connect a first pole of a force power supply in a Kelvin testing circuit; and a second electrical connection point, configured to connect a first terminal of a detecting device in the Kelvin testing circuit, wherein the first electrical connection point and the second electrical connection point are connected with each other within the semiconductor chip, and the first pole of the force power supply and the first terminal of the detecting device are arranged on the same side of the Kelvin testing circuit. According to the present disclosure, the semiconductor chip can be electrically tested with an enhanced accuracy and no impact from external contact and conduction resistances.

### RELATED APPLICATIONS

This application is a continuation application of International Patent Application No. PCT/CN2019/103420, filed on Aug. 29, 2019, which is based on and claims priority to and benefits of Chinese Patent Application Nos. 201811037719.7, and No. 201821459275.1, both filed with the State Intellectual Property Office (SIPO) of the People's Republic of China on Sep. 6, 2018. The entire contents of the above-identified applications are incorporated herein by reference.

### TECHNICAL FIELD

The present disclosure relates to the field of semiconductor technology and, in particular, to semiconductor chips, and circuits and methods for electrically testing semiconductor chips.

### BACKGROUND

In semiconductor manufacturing process, electrical testing of semiconductor chips on undiced wafers, commonly known as “circuit probing” (CP), and electrical testing of individual packaged semiconductor chips, commonly known as “final test” (FT), are necessary.

In current CP practices, as shown in FIG. 1, a probe card is extended from a tester, and probes on the probe card are usually brought into contact with test pads on a semiconductor chip. Force signals are applied to the semiconductor chip by the tester through the probes, and sense signals are then recorded, thereby deriving an electrical profile of the semiconductor chip. In current FT practices, as shown in FIG. 2, a load board is extended from a tester, and a socket is extended from the load board. The tester is usually brought into contact with pins of a semiconductor chip through the socket so as to apply force signals thereto, followed by recording of sense signals and derivation of an electrical profile of the semiconductor chip. Therefore, in both CP and FT practices, the tester and the semiconductor chip are intervened by multiple conductive mediums, which, however, introduce undesired contact resistances including, for example, contact resistances between the chip and the probes, between the probes and the tester, between the chip and the socket, between the socket and the load board, and so on. In addition, the conductive mediums and leads themselves possess conduction resistances. Each of such resistances may affect the force signals applied to the chip and the sense signals recorded by the tester, and result in a reduction in test accuracy.

The information disclosed in this Background section is provided only for the purpose of having a better understanding of the background of the present invention, and does not necessarily constitute prior art already known to a person of ordinary skill in the art.

### SUMMARY OF THE INVENTION

An object of the present disclosure is to provide a semiconductor chip, and a circuit and a method for electrically testing a semiconductor chip, which at least partially overcome the problem of low accuracy in electrical test of semiconductor chips.

Additional features and advantages of the present disclosure will become apparent from the following detailed description, or may be partially learned by practicing the disclosure.

One aspect of the present disclosure presents a semiconductor chip comprising a first electrical connection point, configured to connect a first pole of a force power supply in a Kelvin testing circuit, and a second electrical connection point, configured to connect a first terminal of a detecting device in the Kelvin testing circuit. The first electrical connection point and the second electrical connection point may be connected with each other within the semiconductor chip, and the first pole of the force power supply and the first terminal of the detecting device may be arranged on a same side of the Kelvin testing circuit.

In an exemplary embodiment of the present disclosure, the semiconductor chip may comprise a third electrical connection point, configured to connect a second pole of the force power supply, and a fourth electrical connection point, configured to connect a second terminal of the detecting device. The third electrical connection point and the fourth electrical connection point may be connected with each other within the semiconductor chip.

In an exemplary embodiment of the present disclosure, the semiconductor chip may be a packaged chip. The first electrical connection point may be a first force pin, and the second electrical connection point may be a first sense pin.

In an exemplary embodiment of the present disclosure, the packaged chip may comprise a first pad configured to respectively connect the first force pin and the first sense pin.

In an exemplary embodiment of the present disclosure, the packaged chip may comprise a second force pin, configured to connect a second pole of the force power supply; a second sense pin, configured to connect a second terminal of the detecting device; and a second pad, configured to respectively connect the second force pin and the second sense pin.

In an exemplary embodiment of the present disclosure, the first pad may comprise a first force pad and a first sense pad, the second pad may comprise a second force pad and a second sense pad. The first force pin, the first sense pin, the second force pin and the second sense pin may be respectively connected to the first force pad, the first sense pad, the second force pad and the second sense pad. The first force pad and the first sense pad may be connected with each other within the packaged chip, and the second force pad and the second sense pad may be connected with each other within the packaged chip as well.

In an exemplary embodiment of the present disclosure, the semiconductor chip may be a chip under test on a wafer. The first electrical connection point may be a force pad on the chip under test, and the second electrical connection point may be a sense pad on the chip under test.

In an exemplary embodiment of the present disclosure, the force pad may be a first force pad and the sense pad may be a first sense pad. The chip under test may comprise a second force pad, configured to connect a second pole of the force power supply, and a second sense pad, configured to connect a second terminal of the detecting device. The first force pad and the first sense pad may be connected with each other within the chip under test; and the second force pad and the second sense pad may be connected with each other within the chip under test as well.

Another aspect of the present disclosure presents a circuit for electrically testing a semiconductor chip. The method may comprise the chip under test, a force power supply, and a detecting device. The force power supply may comprise a first pole connecting a first electrical connection point of the chip under test, thereby forming a force loop of a Kelvin testing circuit. The detecting device may comprise a first terminal connecting a second electrical connection point of the chip under test, thereby forming a sense loop of the Kelvin testing circuit. The first electrical connection point and the second electrical connection point may be connected with each other within the chip under test, and the first pole of the force power supply and the first terminal of the detecting device may be arranged on a same side of the Kelvin testing circuit.

In an exemplary embodiment of the present disclosure, the chip under test may comprise a third electrical connection point, configured to connect a second pole of the force power supply, and a fourth electrical connection point, configured to connect a second terminal of the detecting device. The third electrical connection point and the fourth electrical connection point may be connected with each other within the chip under test.

In an exemplary embodiment of the present disclosure, a total resistance of the sense loop may be greater than 10MΩ.

A further aspect of the present disclosure presents a method for electrically testing a semiconductor chip. The method may comprise connecting a first pole of a force power supply to a first electrical connection point of the chip under test to form a force loop of a Kelvin testing circuit; connecting a first terminal of a detecting device to a second electrical connection point of the chip under test to form a sense loop of the Kelvin testing circuit; adjusting a force signal output from the force power supply based on a sense signal detected by the detecting device; and deriving an electrical parameter or an electrical profile of the chip under test based on the sense signal and the force signal. The first electrical connection point and the second electrical connection point may be connected with each other within the chip under test, and the first pole of the force power supply and the first terminal of the detecting device may be arranged on a same side of the Kelvin testing circuit.

In an exemplary embodiment of the present disclosure, the force power supply may comprise a force current source, and the detecting device may comprise a voltage detecting device. The adjusting the force signal output from the force power supply based on the sense signal detected by the detecting device may comprise adjusting a current signal output from the force current source based on a voltage signal detected by the voltage detecting device until the voltage signal reaches an operating voltage of the chip under test. The deriving the electrical parameter or the electrical profile of the chip under test based on the sense signal and the force signal may comprise deriving an I-V curve of the chip under test based on the voltage signal and the current signal.

Exemplary embodiments of the present disclosure have the following beneficial effects.

The present disclosure arranges a first electrical connection point in the semiconductor chip to connect with the first pole of the force power supply in the Kelvin testing circuit, and a second electrical connection point in the semiconductor chip to connect with the first terminal of the detecting device in the Kelvin testing circuit, respectively. In one aspect, by connecting with the force power supply and the detecting device in a particular manner, a Kelvin testing circuit is built. As the Kelvin connection points are arranged within the semiconductor chip, the internal electrical property of the semiconductor chip can be accurately measured, without the impacts of contact resistances and conduction resistances between the tester and the semiconductor chip. Therefore, an increased test accuracy can be achieved. In another aspect, the semiconductor chips in the exemplary examples are simple in structure and can be easily fabricated, and are suitable for use in a wide range of applications.

It is to be understood that both the foregoing general description and the following detailed description are merely for exemplary and explanatory purposes, and does not impose any restriction on the scope of this disclosure.

### BRIEF DESCRIPTION OF THE DRAWINGS

The accompanying drawings, which are incorporated in and constitute a part of the description, illustrate embodiments consistent with the present disclosure and, together with the description, serve to explain the disclosed principles. It is apparent that these drawings present only some embodiments of the disclosure and person of ordinary skill in the art may obtain drawings of other embodiments from them without exerting any creative effort.

FIG. 1 is a schematic of a current semiconductor circuit probing (CP) practice.

FIG. 2 is a schematic of a current semiconductor circuit final test (FT) practice.

FIG. 3 is a schematic of an approach for electrically testing a semiconductor chip according to related art.

FIG. 4a is a schematic of a semiconductor chip according to an exemplary embodiment of the present disclosure.

FIG. 4b is a schematic of another semiconductor chip according to an exemplary embodiment of the present disclosure.

FIG. 5a is a schematic of a first packaged semiconductor chip according to an exemplary embodiment of the present disclosure.

FIG. 5b is a schematic of a second packaged semiconductor chip according to an exemplary embodiment of the present disclosure.

FIG. 5c is a schematic of a third packaged semiconductor chip according to an exemplary embodiment of the present disclosure.

FIG. 5d is a schematic of a fourth packaged semiconductor chip according to an exemplary embodiment of the present disclosure.

FIG. 5e is a schematic of a fifth packaged semiconductor chip according to an exemplary embodiment of the present disclosure.

FIG. 6a is a schematic of a first semiconductor chip on a wafer according to an exemplary embodiment of the present disclosure.

FIG. 6b is a schematic of a second semiconductor chip on a wafer according to an exemplary embodiment of the present disclosure.

FIG. 7a is a schematic of a circuit for electrically testing a semiconductor chip according to an exemplary embodiment of the present disclosure.

FIG. 7b is a schematic of another circuit for electrically testing a semiconductor chip according to an exemplary embodiment of the present disclosure.

FIG. 8 is a flowchart of a method for electrically testing a semiconductor chip according to an exemplary embodiment of the present disclosure.

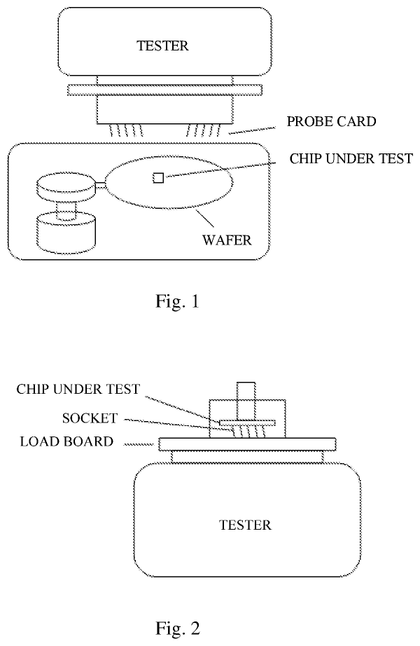

### DETAILED DESCRIPTION

Exemplary embodiments will now be described in details with reference to the accompanying drawings. However, these exemplary embodiments can be implemented in many forms and should not be construed as being limited to those set forth herein. Rather, these embodiments are presented to provide a full and thorough understanding of the present invention and to fully convey the concepts of the exemplary embodiments to others skilled in the art. In addition, the described features, structures, and properties may be combined in any suitable manner in one or more embodiments.

As used herein, the terms “comprising” and “provided” are intended to be used in an open-ended sense to mean that there are possibly other element(s)/component(s)/etc. apart from the listed element(s)/component(s)/etc. As used herein, the terms “first”, “second”, etc. are meant as labels rather than place an ordinal or quantitative limitation upon the mentioned items.

In an approach according to the related art, electrical test of a semiconductor chip is accomplished with a Kelvin testing circuit. On each side of the chip under test with the Kelvin testing circuit, a force line and a sense line are connected to each other at a junction known as a Kelvin connection point. An electrical parameter measured by the sense loop is the electrical parameter between the Kelvin connection points. As shown in FIG. 3, by bringing a socket on a load board or a probe on a probe card into contact with the chip, adverse impacts of resistances upstream of the Kelvin connection points (the junctions between the force lines and sense lines, indicated at P in the figure), i.e., resistances within the Kelvin testing circuit can be eliminated, including internal resistances of the tester, contact resistances between the tester and the load board or probe card, and line resistances upstream of the Kelvin connection points. However, in this approach, since the Kelvin connection points are arranged on the load board or probe card which is located upstream of the chip, resistances downstream of the Kelvin connection points, including contact resistances between the chip and the socket or the probe, and conduction resistances of the socket or probes, cannot be eliminated. Thus, it is difficult for this approach to provide a satisfactory test accuracy.

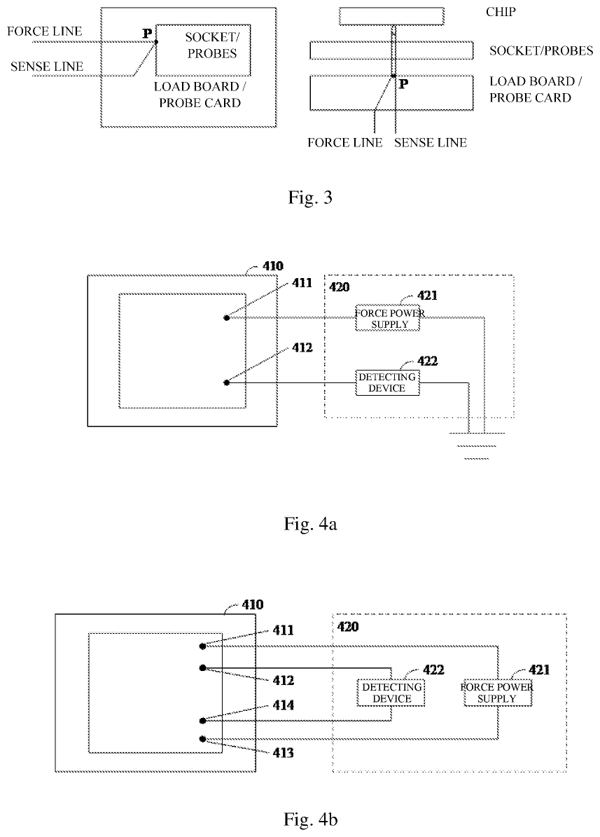

In view of the above, according to one exemplary embodiment of the present disclosure, a semiconductor chip suitable to be electrically tested is provided. Referring to FIG. 4a, the semiconductor chip 410 may include a first electrical connection point 411, and a second electrical connection point 412. The first electrical connection point 411 is configured to connect a first pole of a force power supply 421 in a Kelvin testing circuit 420, and the second electrical connection point 412 is configured to connect a first terminal of a detecting device 422 in the Kelvin testing circuit 420. The first electrical connection point 411 and the second electrical connection point 412 may be connected with each other within the semiconductor chip 410, and the first pole of the force power supply 421 and the first terminal of the detecting device 422 may be arranged on a same side of the Kelvin testing circuit 420.

Each of the electrical connection points is arranged in the semiconductor chip, which is configured to establish an electrical connection between an external device outside the chip and an internal component inside the chip, such as a pin of a packaged chip, a pad of an unpackaged chip, etc. The force power supply 421 may either be a current source or a voltage source. When the force power supply 421 is a DC power source, the first pole may either be positive or negative. The detecting device 422 may be an electrical meter, such as a voltmeter, an ammeter, an oscilloscope, a measuring module inside a tester, etc. In general, the electrical meter has two terminals, such as the voltmeter and the ammeter. When the first pole of the force power supply 421 is positive, the first terminal of the detecting device 422 may be a high-level terminal. The internal connection of the first electrical connection point 411 and the second electrical connection point 412 within the semiconductor chip 410 is intended to mean that both electrical connection points are corresponding to a same functional region of a component in the semiconductor chip 410, and are thus considered equivalent to each other. For example, the first electrical connection point 411 and second electrical connection point 412 may be two electrical connection points both arranged in a same source region of a metal-oxide-semiconductor field-effect transistor (MOSFET). The first electrical connection point 411 may be connected to the force power supply 421 to form a force loop in the Kelvin testing circuit, and the second electrical connection point 412 may be connected to the detecting device 422 to form a sense loop in the Kelvin testing circuit. Since the first electrical connection point 411 is connected to the second electrical connection point 412, the force loop is connected to the sense loop at the first electrical connection point 411 and second electrical connection point 412, thus a Kelvin connection point is formed. More specifically, since the detecting device 422 is connected to the semiconductor chip 410 at the second electrical connection point 412, the second electrical connection point 412 may be considered as the Kelvin connection point in this embodiment.

In different tests, the roles of the first electrical connection point 411 and the second electrical connection point 412 may be interchanged. That is, each of the electrical connection points may be connected to the force power supply in some tests, and be connected to the detecting device in some other tests. The present disclosure is not particularly limited in this regard.

A second pole of the force power supply 421 and a second terminal of the detecting device 422 may be arranged on the other side of the Kelvin testing circuit 420, and may either be grounded or connected to other positions in the semiconductor chip 410.

The semiconductor chip 410 shown in FIG. 4a may be configured for use with a single-ended Kelvin test approach in which the Kelvin testing circuit measures an electrical property between a single point or position of semiconductor chip 410 and the ground. In this case, the second pole of the force power supply 421 and the second terminal of the detecting device 422 are both grounded. A corresponding ground point, i.e., another Kelvin connection point, may be formed within the semiconductor chip 410, such as in a drain terminal of the MOSFET. The detecting device 422 may be configured to detect an electrical property between the second electrical connection point 412 of the semiconductor chip 410 and the ground point, i.e., an internal electrical property of the semiconductor chip 410.

The semiconductor chip 410 of FIG. 4b may be configured for use with a double-ended Kelvin test approach in which the Kelvin testing circuit measures an electrical property between two points or positions of semiconductor chip 410. Referring to FIG. 4b, according to an exemplary embodiment, the semiconductor chip 410 may further include a third electrical connection point 413, configured to connect the second pole of the force power supply 421, and a fourth electrical connection point 414, configured to connect the second terminal of the detecting device 422. The third electrical connection point 413 and the fourth electrical connection point 414 may be connected to each other within the semiconductor chip 410.

In this case, two Kelvin connection points are formed respectively at the second electrical connection point 412 and the fourth electrical connection point 414. The detecting device 422 may measure an electrical property between the second electrical connection point 412 and the fourth electrical connection point 414 in the semiconductor chip 410.

The above exemplary embodiments arrange the first electrical connection point in the semiconductor chip to connect with the first pole of the force power supply in the Kelvin testing circuit, and the second electrical connection point in the semiconductor chip to connect with the first terminal of the detecting device in the Kelvin testing circuit, respectively. In one aspect, by connecting with the force power supply and the detecting device in a particular manner, a Kelvin testing circuit is built. As the Kelvin connection points are arranged within the semiconductor chip, the internal electrical property of the semiconductor chip can be accurately measured, without the impacts of contact resistances and conduction resistances between the tester and the semiconductor chip. Therefore, an increased test accuracy can be achieved. In another aspect, the semiconductor chips in the above exemplary embodiments are simple in structure and can be easily fabricated, and are suitable for use in a wide range of applications.

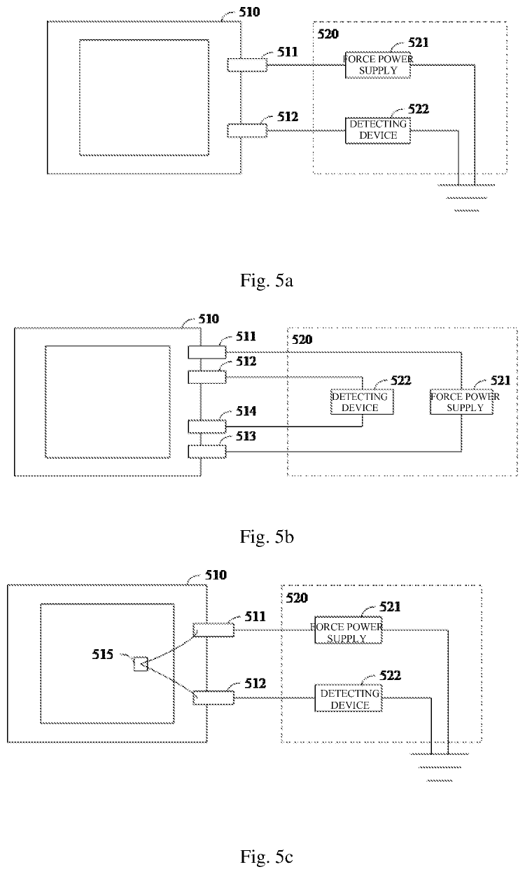

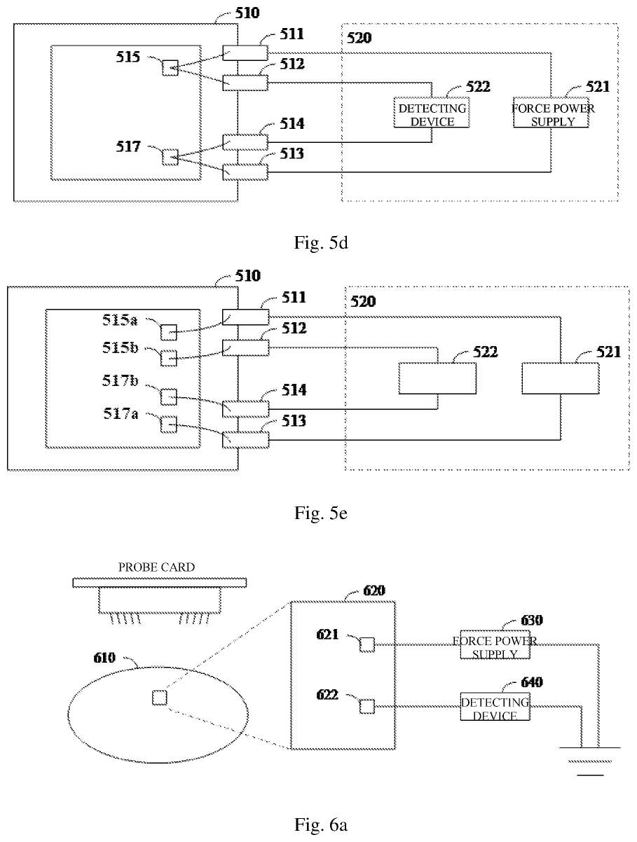

According to an exemplary embodiment, as shown in FIG. 5a, the semiconductor chip may be a packaged chip 510. In this case, the first electrical connection point may be a first force pin 511 in the packaged chip 510, which is connected to the first pole of the force power supply 521 in the Kelvin testing circuit 520. The second electrical connection point is a first sense pin 512 in the packaged chip 510, which is connected to the first terminal of the detecting device 522 in the Kelvin testing circuit 520. Since the first electrical connection point is connected to the second electrical connection point within the packaged chip 510, namely, the first force pin 511 is connected with the first sense pin 512 within the packaged chip 510, a corresponding Kelvin connection point may be formed within the packaged chip 510, eliminating possible impacts of any contact resistance or conduction resistance caused by connecting the first force pin 511 or the first sense pin 512 to the packaged chip 510, and thus enhancing a test accuracy.

As shown in FIG. 5a, the second pole of the force power supply 521 and the second terminal of the detecting device 522 may be both grounded. As shown in FIG. 5b, the second pole of the force power supply 521 and the second terminal of the detecting device 522 may be alternatively connected to other positions in the packaged chip 510. As shown in FIG. 5b, the packaged chip 510 may further comprise a second force pin 513 and a second sense pin 514. The second pole of the force power supply 521 may be connected to the second force pin 513, and the second terminal of the detecting device 522 may be connected to the second sense pin 514, respectively. Thus, the detecting device 522 may be used to measure an internal electrical property of the packaged chip 510.

According to an exemplary embodiment, as shown in FIG. 5c, the packaged chip 510 may further include a first pad 515 configured to connect both the first force pin 511 and the first sense pin 512. The first pad 515 may be a test pad of the packaged chip 510, which is configured for electrical testing, or to which a lead may be soldered. The first pad 515 may be connected to the first force pin 511 and the first sense pin 512 by leads, conductive material fillers, metal sheets extending deeply into the chip, or the like. The present disclosure is not particularly limited in this regard. By connecting the first pad 515 to the first force pin 511 and the first sense pin 512, the first pad 515 indirectly connects to the first pole of the force power supply 521 and the first terminal of the detecting device 522, thus forming a Kelvin connection point at the first pad 515. Thus, the detecting device 522 may be used to measure an electrical property between the first pad 515 and the ground.

Moreover, referring to FIG. 5d, the packaged chip 510 may further include a second force pin 513, a second sense pin 514, and a second pad 517. The second force pin 513 is configured to connect the second pole of the force power supply 521, and the second sense pin 514 is configured to connect the second terminal of the detecting device 522. The second pad 517 is configured to connect both the second force pin 513 and the second sense pin 514. In this way, Kelvin connection points may be formed respectively at the first pad 515 and the second pad 517. Thus, the detecting device 522 may be used to measure an electrical property between the first pad 515 and the second pad 517. This allows a well-defined range of electrical testing, without the impacts from external resistances.

Further, referring to FIG. 5e, the first pad 515 may further include a first force pad 515a and a first sense pad 515b, and the second pad 517 may further include a second force pad 517a and a second sense pad 517b. The first force pin 511 may be connected to the first force pad 515a, the first sense pin 512 may be connected to the first sense pad 515b, the second force pin 513 may be connected to the second force pad 517a, and the second sense pin 514 may be connected to the second sense pad 517b, respectively. Additionally, the first force pad 515a and the first sense pad 515b may be connected with each other within the packaged chip 510, and the second force pad 517a and the second sense pad 517b may be connected with each other within the packaged chip 510.

Likewise, the internal connection of the first force pad 515a and the first sense pad 515b within the packaged chip 510 is intended to mean that both the pads are corresponding to a same functional region of a component in the packaged chip 510, and are thus considered equivalent to each other. Therefore, a Kelvin connection point may be formed at the first force pad 515a or at the first sense pad 515b. More specifically, since the detecting device 522 is connected to the packaged chip 510 at the first sense pad 515b, the first sense pad 515b may be considered as a Kelvin connection point in this embodiment. Similarly, the second sense pad 517b may be considered as another Kelvin connection point. Thus, the detecting device 522 may be used to measure an electrical property between the first sense pad 515b and the second sense pad 517b.

By arranging each of the four pads to be respectively connected to a corresponding pin, the connections between the pads and the pins may be accomplished with an even simpler process.

In alternative embodiments, the packaged chip may only include any three of the aforementioned four pads. For example, the first pad may be implemented as a single pad, while the second pad may include the second force pad and the second sense pad. In this case, both the first force pin and the first sense pin may be connected to the first pad. While the second force pin may be connected to the second force pad, and the second sense pin may be connected to the second sense pad, respectively. Alternatively, the first pad may include the first force pad and the first sense pad, while the second pad may be implemented as a single pad. In this case, the first force pin may be connected to the first force pad, and the first sense pin may be connected to the first sense pad, respectively. While both the second force pin and the second sense pin may be connected to the second pad. However, the present disclosure is not particularly limited in this regard.

In the above embodiments, the first force pin 511, the first sense pin 512, the second force pin 513 and the second sense pin 514 are spaced apart from, and do not contact with, one another externally to the packaged chip 510. Therefore, there is no Kelvin connection point formed outside the packaged chip 510, and both the Kelvin connection points are formed within the packaged chip 510. Additionally, in different tests, the roles of the first force pin 511 and the first sense pin 512, as well as the roles of the second force pin 513 and the second sense pin 514, may be interchanged. That is, each of the pins may be used as a force pin in some tests, and may be used as a sense pin in some other tests, the present disclosure is not particularly limited in this regard.

It is to be noted that, in order to ensure that the Kelvin connection points are precisely located at desired positions within the packaged chip, the connection mediums (e.g., conductive lines, conductive material fillers, etc.) between the pins and the desired positions may be insulated and physically fixed, for example, by insulating material fillers. In this way, dislodgement of the Kelvin connection points and corresponding resistances caused thereof can be reduced.

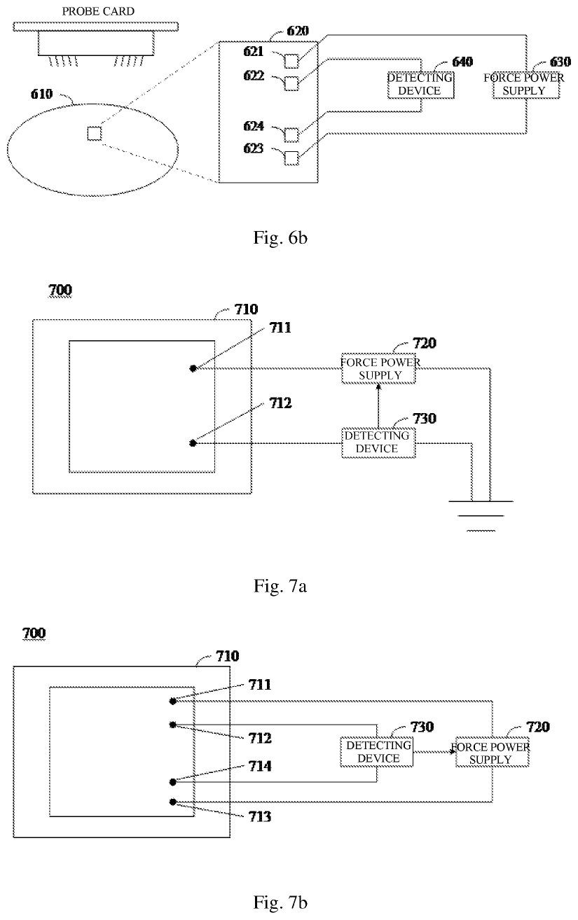

According to an exemplary embodiment, referring to FIG. 6a, the semiconductor chip may be a chip under test 620 on a wafer 610. In this case, the first electrical connection point may be a first force pad 621 on the chip under test 620, while the second electrical connection point may be a first sense pad 622 on the chip under test 620.

In addition, the first force pad 621 may be connected to the first pole of the force power supply 630 in the Kelvin testing circuit, and the first sense pad 622 may be connected to the first terminal of the detecting device 640 in the Kelvin testing circuit. The aforementioned connections within the chip under test 620 on a wafer 610 are usually accomplished with probes. Since the first electrical connection point is connected to the second electrical connection point within the chip under test 620, namely, the first force pad 621 is connected with the first sense pad 622 within the chip under test 620, a Kelvin connection point may be formed within the chip under test 620, thus eliminating possible impacts of contact resistances between the probes and the pads, and conduction resistances of the probes themselves. Therefore, an enhanced test accuracy can be achieved.

As shown in FIG. 6a, the second pole of the force power supply 630 and the second terminal of the detecting device 640 may be both grounded. As shown in FIG. 6b, the second pole of the force power supply 630 and the second terminal of the detecting device 640 may be alternatively connected to other positions in the chip under test 620. According to an exemplary embodiment, as shown in FIG. 6b, the chip under test 620 may further include a second force pad 623 and a second sense pad 624. The second force pad 623 is configured to connect the second pole of the force power supply 630, and the second sense pad 624 is configured to connect the second terminal of the detecting device 640. Additionally, the first force pad 621 may be connected with the first sense pad 622 within the chip under test 620, and the second force pad 623 may be connected with the second sense pad 624 within the chip under test 620 as well. In this way, Kelvin connection points may be formed respectively at the first sense pad 622 and the second sense pad 624. Thus, the detecting device 640 may be used to measure an internal electrical property of the chip under test 620 between the first sense pad 622 and the second sense pad 624.

It is to be noted that, in the above embodiments, no matter the semiconductor chip is a packaged chip or a chip on a wafer, the number of pads or pins thereon is not limited to those listed above. For example, the chip under test on a wafer may contain multiple components or functional regions, each of which may be provided with a corresponding pair of a first pad and a second pad (or a force pad and a sense pad). In addition, there may be other pads performing other functions, and the number of pads in the chip may be any number that is not smaller than two. Similarly, the packaged chip may contain multiple components or functional regions, each of which may be provided with a corresponding pair of a first force pin and a first sense pin. In addition, there may be other pins performing other functions, and the number of pins in the chip may be any number that is not smaller than two. The present disclosure is not particularly limited in this regard.

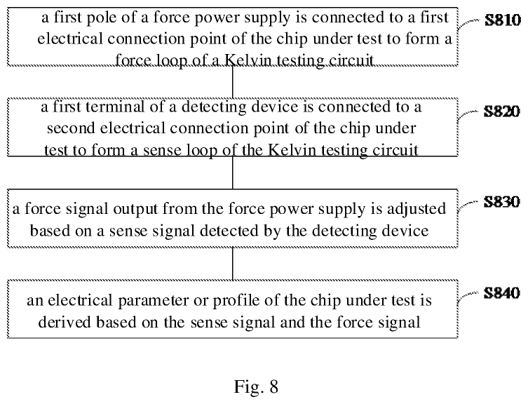

In an exemplary embodiment of the present disclosure, a circuit for electrically testing a semiconductor chip is provided. The circuit may be configured to perform a FT test on a packaged chip, or a CP test on an undiced chip on a wafer. Referring to FIG. 7a, the circuit 700 may include the chip under test 710, a force power supply 720 and a detecting device 730. The force power supply 720 may have a first pole which is connected to a first electrical connection point 711 in the chip under test 710, thereby forming a force loop of a Kelvin testing circuit. The detecting device may have a first terminal which is connected to a second electrical connection point 712 in the chip under test 710, thereby forming a sense loop of the Kelvin testing circuit. The first electrical connection point 711 may be connected with the second electrical connection point 712 within the chip under test 710, and the first pole of the force power supply 720 and the first terminal of the detecting device 730 may be arranged on a same side of the Kelvin testing circuit. Since the first electrical connection point 711 is connected with the second electrical connection point 712, the force loop is connected to the sense loop at the first electrical connection point 711 and the second electrical connection point 712, thus a Kelvin connection point is formed. More specifically, since the detecting device 730 is connected to the chip under test 710 at the second electrical connection point 712, the second electrical connection point 712 may be considered as the Kelvin connection point in this embodiment.

As shown in FIG. 7a, a second pole of the force power supply 720 and a second terminal of the detecting device 730 may be both grounded. Thus, the detecting device 730 may be used to measure an electrical property between the second electrical connection point 712 of the chip under test 710 and the ground, i.e., an internal electrical property of the chip under test 710. In other embodiments, the second pole of the force power supply 720 and the second terminal of the detecting device 730 may be alternatively connected to other positions in the chip under test 710.

According to an exemplary embodiment, referring to FIG. 7b, the chip under test 710 may further include a third electrical connection point 713 and a fourth electrical connection point 714. The third electrical connection point 713 is connected to the second pole of the force power supply 720, and the fourth electrical connection point 714 is connected to the second terminal of the detecting device 730, wherein the third electrical connection point 713 and the fourth electrical connection point 714 are connected with each other within the chip under test 710. In this case, two Kelvin connection points may be formed respectively at the second electrical connection point 712 and the fourth electrical connection point 714. Thus, the detecting device 730 may be used to measure an electrical property between the second electrical connection point 712 and the fourth electrical connection point 714 point in the chip under test 710.

According to an exemplary embodiment, the sense loop may have a total resistance greater than 10 MΩ. In practice, each line in the sense loop has a parasitic resistance, which may lead to a voltage drop across the line upon a current flowing therein and thus decrease the test accuracy. In order to minimize the voltage drop, a relatively great resistance may be introduced into the sense loop. In general, a total resistance of the sense loop greater than 10 MΩ may be considered to be infinite when compared to the resistance of the chip under test. In this case, the current in the sense loop and the voltage drop across the line may be considered to be close to zero. Therefore, an enhanced test accuracy can be achieved.

According to an exemplary embodiment, the force power supply may be a force current source, and the detecting device may be a voltage detecting device. In this case, a current output from the force current source is equal to a current following in the chip under test, and a voltage detected by the voltage detecting device is equal to a voltage drop across the chip under test. By recording these two parameters, a resistance or an I-V curve of the chip under test may be derived.

Referring to FIG. 7a and FIG. 7b, the detecting device 730 may generate a feedback to the force power supply 720. When the value of the electrical parameter measured by the detecting device 730 exceeds or falls short of an operating parameter of the chip under test, a power of the force power supply 720 may be adjusted to the extent allowing the force signal applied to the chip under test 710 falls somewhere in the range of the operating parameter of the chip. Thus, results of electrical testing within such range may be derived.

According to an exemplary embodiment of the present disclosure, a method for electrically testing a semiconductor chip is provided. Referring to FIG. 8, the method may include the following steps S810 through S840.

In step S810, a first pole of a force power supply is connected to a first electrical connection point of the chip under test to form a force loop of a Kelvin testing circuit.

In step S820, a first terminal of a detecting device is connected to a second electrical connection point of the chip under test to form a sense loop of the Kelvin testing circuit.

In step S830, a force signal output from the force power supply is adjusted based on a sense signal detected by the detecting device.

In step S840, an electrical parameter or profile of the chip under test is derived based on the sense signal and the force signal.

The first electrical connection point may be connected with the second electrical connection point within the chip under test. And the first pole of the force power supply and the first terminal of the detecting device may be arranged on a same side of the Kelvin testing circuit.

The force power supply may either be a current source or a voltage source. When the force power supply is a DC power source, the first pole may either be positive or negative. The detecting device may be an electrical meter with two terminals, such as a voltmeter, an ammeter, an oscilloscope, a measuring module inside a tester, etc. In general, the detecting device may comprise two terminals, such as the voltmeter and the ammeter. When the first pole of the force power supply is positive, the first terminal of the detecting device may be a high-level terminal. Either the first electrical connection point or the second electrical connection point of the chip under test may form a first Kelvin connection point. When a second pole of the force power supply and a second terminal of the detecting device are both grounded, a second Kelvin connection point may be formed at the ground point. In this case, a sense signal detected by the detecting device, i.e., an actual signal output from the chip under test, may be a response signal between the first electrical connection point or the second electrical connection point of the chip under test and the ground. When the second pole of the force power supply and the second terminal of the detecting device are respectively connected to other electrical connection points of the chip under test, a second Kelvin connection point may be formed at these other electrical connection points. In this case, a sense signal detected by the detecting device, i.e., an actual signal output from the chip under test, may be a response signal between two electrical connection points of the chip under test. Based on the sense signal, the force signal may be adjusted to the extent allowing the sense signal reaches a desired level. With the force signal and the sense signal, an electrical parameter or profile of the chip under test may be derived. And an enhanced test accuracy can be achieved.

According to an exemplary embodiment, the first pole of the force power supply may be connected to the first electrical connection point of the chip under test, and the second pole of the force power supply may be connected to the third electrical connection point of the chip under test, respectively, to form the force loop of the Kelvin testing circuit. Additionally, the first terminal of the detecting device may be connected to the second electrical connection point of the chip under test, and the second terminal of the detecting device may be connected to the fourth electrical connection point of the chip under test, respectively, to form the sense loop of the Kelvin testing circuit. In this way, the detecting device may be used to measure an electrical property between the second electrical connection point and the fourth electrical connection point of the chip under test, i.e., an internal electrical property of the chip under test.

According to an exemplary embodiment, the force power supply may be a force current source, while the detecting device may be a voltage detecting device. In this case, step S830 may include: adjusting a current signal output from the force current source based on a voltage signal detected by the voltage detecting device, to the extent that the voltage signal reaches an operating voltage of the chip under test. Further, step S840 may include: deriving an I-V curve of the chip under test based on the voltage signal and the current signal.

The operating voltage may either be a discrete value, or a time-voltage curve. By recording current signals output from the force current source and voltage signals detected by the voltage detecting device at a series of moments, the I-V curve of the chip under test may be plotted. The I-V curve is one of the main representations of electrical property of the semiconductor chip. Based on the I-V curve, other electrical parameters of the chip under test, such as resistance, capacitance, inductance or the like, can be calculated. The present invention is not limited to any particular form of the results of the electrical test.

It is to be noted that the represented blocks in the figures are purely functional entities, which do not necessarily correspond to physically separated entities. In other words, these functional entities may be implemented by software, or in one or more software-hardened modules entirely or partially, or in different networks and/or processor devices and/or microcontroller devices.

Other embodiments of the present disclosure will be apparent to those skilled in the art by considering the specification and practicing the invention disclosed herein. Accordingly, this present disclosure is intended to cover all and any variations, uses, or adaptations of the disclosure which follow, in general, the principles thereof and include such departures from the present disclosure as come within common knowledge or customary practice within the art to which the invention pertains. It is also intended that the specification and examples be considered as exemplary only, with true scope and spirit of the disclosure being indicated by the appended claims.

It is to be understood that the present disclosure is not limited to the exact structures as described above and illustrated in the figures, and may be modified or changed without departing from its scope. The scope of the disclosure is intended to be defined only by the appended claims.

What is claimed is:

1. A semiconductor chip, comprising:
a first electrical connection point, configured to connect a first pole of a force power supply in a Kelvin testing circuit; and
a second electrical connection point, configured to connect a first terminal of a detecting device in the Kelvin testing circuit,
wherein the first electrical connection point and the second electrical connection point are connected with each other within the semiconductor chip, and the first pole of the force power supply and the first terminal of the detecting device are arranged on a same side of the Kelvin testing circuit.

2. The semiconductor chip of claim 1, further comprising:
a third electrical connection point, configured to connect a second pole of the force power supply; and
a fourth electrical connection point, configured to connect a second terminal of the detecting device,
wherein the third electrical connection point and the fourth electrical connection point are connected with each other within the semiconductor chip.

3. The semiconductor chip of claim 1, wherein the semiconductor chip is a packaged chip, and wherein the first electrical connection point is a first force pin and the second electrical connection point is a first sense pin.

4. The semiconductor chip of claim 3, wherein the packaged chip further comprises:
a first pad, configured to respectively connect the first force pin and the first sense pin.

5. The semiconductor chip of claim 4, wherein the packaged chip further comprises:
a second force pin, configured to connect a second pole of the force power supply;
a second sense pin, configured to connect a second terminal of the detecting device; and
a second pad, configured to respectively connect the second force pin and the second sense pin.

6. The semiconductor chip of claim 5, wherein: the first pad comprises a first force pad and a first sense pad, the second pad comprises a second force pad and a second sense pad, and the first force pin, the first sense pin, the second force pin and the second sense pin are respectively connected to the first force pad, the first sense pad, the second force pad and the second sense pad, and
wherein the first force pad and the first sense pad are connected with each other within the packaged chip, and the second force pad and the second sense pad are connected with each other within the packaged chip as well.

7. The semiconductor chip of claim 1, wherein the semiconductor chip is a chip under test on a wafer, wherein the first electrical connection point is a force pad on the chip under test, and wherein the second electrical connection point is a sense pad on the chip under test.

8. The semiconductor chip of claim 7, wherein the force pad is a first force pad and the sense pad is a first sense pad, wherein the chip under test further comprises:
a second force pad, configured to connect a second pole of the force power supply; a second sense pad, configured to connect a second terminal of the detecting device; and
wherein the first force pad and the first sense pad are connected with each other within the chip under test; and the second force pad and the second sense pad are connected with each other within the chip under test as well.

9. A circuit for electrically testing a semiconductor chip, comprising:
a chip under test;
a force power supply, comprising a first pole connecting a first electrical connection point of the chip under test, thereby forming a force loop of a Kelvin testing circuit; and
a detecting device, comprising a first terminal connecting a second electrical connection point of the chip under test, thereby forming a sense loop of the Kelvin testing circuit,
wherein the first electrical connection point and the second electrical connection point are connected with each other within the chip under test, and the first pole of the force power supply and the first terminal of the detecting device are arranged on a same side of the Kelvin testing circuit.

10. The circuit of claim 9, wherein the chip under test further comprises:
a third electrical connection point, configured to connect a second pole of the force power supply
a fourth electrical connection point, configured to connect a second terminal of the detecting device,
wherein the third electrical connection point and the fourth electrical connection point are connected with each other within the chip under test.

11. The circuit of claim 9, wherein a total resistance of the sense loop is greater than 10MΩ.

12. A method for electrically testing a semiconductor chip, comprising:
connecting a first pole of a force power supply to a first electrical connection point of a chip under test to form a force loop of a Kelvin testing circuit;
connecting a first terminal of a detecting device to a second electrical connection point of the chip under test to form a sense loop of the Kelvin testing circuit;
adjusting a force signal output from the force power supply based on a sense signal detected by the detecting device; and
deriving an electrical parameter or an electrical profile of the chip under test based on the sense signal and the force signal,
wherein the first electrical connection point and the second electrical connection point are connected with each other within the chip under test, and the first pole of the force power supply and the first terminal of the detecting device are arranged on a same side of the Kelvin testing circuit.

13. The method of claim 12, wherein the force power supply comprises a force current source and the detecting device comprises a voltage detecting device,
wherein the adjusting the force signal output from the force power supply based on the sense signal detected by the detecting device comprises:
adjusting a current signal output from the force current source based on a voltage signal detected by the voltage detecting device until the voltage signal reaches an operating voltage of the chip under test, and
wherein the deriving the electrical parameter or the electrical profile of the chip under test based on the sense signal and the force signal comprises:
deriving an I-V curve of the chip under test based on the voltage signal and the current signal.
